(19) United States
(12) Patent Application Publication
(10) Pub. No.: US 2012/0073627 A1
(43) Pub. Date: Mar. 29, 2012

(54) SOLAR CELL MODULE

(75) Inventor: Shunpei YAMAZAKI, Tokyo (JP)

(73) Assignee: SEMICONDUCTOR ENERGY LABORATORY CO., LTD., Atsugi-shi (JP)

(21) Appl. No.: 13/246,366

(22) Filed: Sep. 27, 2011

(30) Foreign Application Priority Data
Sep. 28, 2010 (JP) 2010-217099

(51) Int. Cl. H01L 31/052

(52) U.S. Cl. 136/246

(57) ABSTRACT

A solar cell module that is prevented from being damaged by the wind and can be installed at low cost is provided. The solar cell module includes a supporting substrate, a plurality of first cells, and a plurality of second cells. The first cell is disposed so as to form an angle a between the first cell and the supporting substrate. The second cell is disposed so as to form an angle b between the second cell and the first cell and so as to form the angle a+the angle b between the second cell and the supporting substrate. A light-receiving surface of the first cell and a light-receiving surface of the second cell face each other. The module can be installed substantially horizontally to the level ground without impairing power generation capability.

### TECHNICAL FIELD

The present invention relates to a solar cell module that can be installed at low cost.

### BACKGROUND ART

In recent years, a solar cell that generates power without carbon dioxide emissions has attracted attention as a countermeasure against global warming. Since the amount of power generation of a solar cell depends on the sunlight illuminance, a solar cell module is generally installed with an inclination angle so as to maximize the annual amount of power generation. Alternatively, in some cases, a solar cell module is installed with an inclination angle so as to maximize the amount of power generation in a season during which the solar altitude is low.

In order to increase the amount of power generation, it is preferable that a solar cell module be installed so as to be perpendicularly irradiated with sunlight as much as possible. For example, in a region where the north latitude is 30° to 40°, a solar cell module may be installed with an azimuth angle of 0° (i.e., the solar cell module faces south) and an inclination angle of 20° to 40°.

In order to install a solar cell module with an appropriate inclination angle in the above manner, a mounting rack is needed. A solar cell module installed with an inclination angle is exposed to the wind from various directions; thus, a mounting rack needs to be strong so as to be able to withstand strong wind. In the case where the strength of a mounting rack is not sufficient, the solar cell module is easily damaged by the wind; for example, it is blown away or displaced due to strong wind.

As a measure to suppress damage by the wind, disclosed in Patent Document 1 is a method in which a leg of a mounting rack is surrounded by a protective plate and the lightweight mounting rack diffuses wind pressure. Further, disclosed in Patent Document 2 is a method in which a spile having an arrowhead portion whose tip is provided with a barb is driven into the ground and a mounting rack is fixed to the spile so that a solar cell module is prevented from being drawn due to wind pressure.

### [Patent Document]

[Patent Document 1] Japanese Published Patent Application No. H08-274364
[Patent Document 2] Japanese Published Patent Application No. H05-3335

### DISCLOSURE OF INVENTION

However, even in the case where the above countermeasures are taken, a solar cell module should be installed so as to be able to withstand wind pressure as required by laws or regulations of a country where the solar cell module is installed and still needs a strong mounting rack.

The proportion of the cost of a mounting rack and the installation cost in the whole building cost of a solar photovoltaic system is higher than or equal to the proportion of the cost of a solar cell module, which is one factor in prohibiting a solar cell photovoltaic system from being in widespread use. Therefore, a countermeasure against damage by the wind, which can also achieve a sufficient cost reduction, has been desired.

Therefore, an object of one embodiment of the present invention is to provide a solar cell module that is prevented from being damaged by the wind and can be installed at low cost.

One embodiment of the present invention disclosed in this specification relates to a solar cell module that can be installed substantially horizontally to the level ground without impairing power generation capability.

One embodiment of the present invention is a solar cell module including a supporting substrate; a plurality of first cells; and a plurality of second cells. The first cell is disposed so as to form an angle a between a bottom surface of the first cell and a top surface of the supporting substrate. The second cell is disposed so as to form an angle b between a bottom surface of the second cell and the bottom surface of the first cell and so as to form the angle a+the angle b between the bottom surface of the second cell and the top surface of the supporting substrate. The first cell and the second cell are disposed so that a light-receiving surface of the first cell and a light-receiving surface of the second cell face each other.

In this specification, the ordinal numbers such as “first” and “second” are given for convenience to distinguish between elements, and they are not given to limit the number, the arrangement, or the order of the steps.

The angle a is preferably greater than or equal to 30° and less than or equal to 60°. The angle b is preferably greater than or equal to 60° and less than or equal to 70°. The light-receiving surface of the first cell and the light-receiving surface of the second cell face each other with the angle b formed therebetween, whereby incident light reflected by the light-receiving surface of one cell enters the light-receiving surface of the other cell. Thus, reflected light is utilized effectively, so that the amount of power generation can be increased.

It is preferable that the first cell and the second cell be electrically connected in parallel. The amount of power generation of the first cell and that of the second cell are different from each other in some cases; therefore, in the case where the first cell and the second cell are connected in series, one of them might function as a resistor, which leads to loss in electric power.

The above solar cell module is preferably installed with an inclination angle greater than or equal to 0° and less than 10° to an installation surface which is substantially parallel to the ground. When the solar cell module is installed with such an angle, the area exposed to the wind can be decreased. In this manner, the solar cell module can be prevented from being damaged by the wind as much as possible.

As described above, in a solar cell module according to one embodiment of the present invention, cells have inclination angles to a supporting substrate, and accordingly sunlight can efficiently enter the cells. Therefore, even when the solar cell module is installed substantially horizontally to the level ground, the amount of power generation can be larger than or equal to that in the case where a solar cell module is installed with an inclination angle.

According to one embodiment of the present invention, a solar photovoltaic system that is prevented from being damaged by the wind and can be installed at low cost can be provided.

### BRIEF DESCRIPTION OF DRAWINGS

FIGS. 1A and 1B are a plan view and a cross-sectional view illustrating a solar cell module.

FIG. 2 is a cross-sectional view illustrating light reflection from a surface of a cell.

FIGS. 3A and 3B are cross-sectional views each illustrating an installation mode of a solar cell module.

### BEST MODE FOR CARRYING OUT THE INVENTION

Hereinafter, an embodiment of the present invention will be described in detail with reference to the accompanying drawings. Note that the present invention is not limited to the description below, and it is easily understood by those skilled in the art that modes and details disclosed herein can be modified in various ways. Therefore, the present invention is not construed as being limited to the description of the embodiment below. Note that in all drawings used to illustrate the embodiment, portions that are identical or portions having similar functions are denoted by the same reference numerals, and their repetitive description may be omitted.

In this embodiment, a structure of a solar cell module according to one embodiment of the present invention and an installation mode thereof will be described.

Note that in this specification, the term “cell” means a solar cell itself, and the term “module” means a structure in which a plurality of cells are electrically connected to each other and fixed between a supporting substrate and a protective substrate.

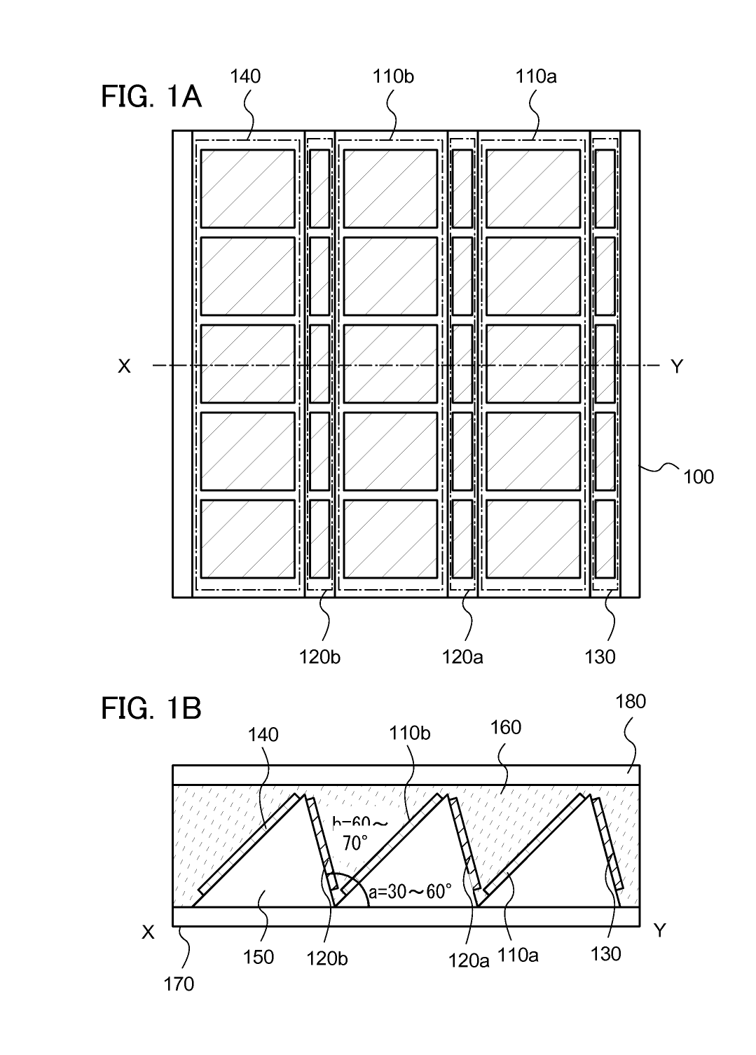

FIGS. 1A and 1B are examples of a plan view and a cross-sectional view, respectively, of a solar cell module according to one embodiment of the present invention. A cross-sectional view taken along line X-Y in FIG. 1A corresponds to FIG. 1B. A solar cell module 100 in this embodiment includes a supporting substrate 170, a cell stand 150, first cells 110a and 110b, second cells 120a and 120b, a third cell 130, a fourth cell 140, a sealing resin 160, and a protective substrate 180. Note that the third cell 130, the fourth cell 140, and the sealing resin 160 may be omitted. Note that a frame for strengthening a structure of the solar cell module and fixing the solar cell module to a mounting rack is not illustrated.

For the supporting substrate 170, a sheet of polyethylene terephthalate (PET), polyethylene naphthalate (PEN), or the like can be used. When a sheet in which an inorganic film of silica or the like is formed on PET or PEN is used, a gas barrier property is improved; thus, deterioration of the cells due to water vapor or the like can be suppressed.

The cell stand 150 has a triangle prism shape, and one side surface thereof is fixed to the supporting substrate 170 side, and cells are fixed to the other side surfaces thereof. The cell stand 150 may have a hollow structure, or may include a battery or a DCDC converter therein. Note that the number of the cell stands 150 is three in FIGS. 1A and 1B; however, it is not particularly limited, and may be determined as appropriate by a practitioner. Further, the cell stand 150 does not necessarily have a box-like shape, and may be formed by bending a plate into a step-like pattern or may be formed by cutting and processing an upper portion of the supporting substrate 170.

There is no particular limitation on a material of the cell, and a solar cell may be formed using a silicon-based material such as single crystal silicon, polycrystalline silicon, or amorphous silicon or a compound semiconductor material such as cadmium telluride (CdTe) or CIGS (Cu(In,Ga)Se₂). Note that FIG. 1A illustrates an example in which five cells are provided on one side surface of the cell stand 150; however, the number of cells is not particularly limited, and may be determined as appropriate by a practitioner. Note that when a thin-film solar cell is used, one sub-module in which solar cells are integrated may be fixed to one side surface of the cell stand 150.

As illustrated in FIGS. 1A and 1B, in the case where three cell stands 150 are provided so as to be adjacent to each other, the first cell 110a is fixed to one side surface of the cell stand on the right side and the third cell 130 is fixed to the other side surface thereof. The first cell 110b is fixed to one side surface of the cell stand at the center, and the second cell 120b is fixed to the other side surface thereof. The fourth cell 140 is fixed to one side surface of the cell stand on the left side, and the second cell 120b is fixed to the other side surface thereof.

In this manner, the first cell 110a and the second cell 120a are fixed so as to face each other and form a V shape, and the first cell 110b and the second cell 120b are fixed so as to face each other and form a V shape. Note that the first cells 110a and 110b are each preferably fixed so as to form an angle a which is greater than or equal to 30° and less than or equal to 60° with respect to the supporting substrate 170. Further, the second cells 120a and 120b are preferably fixed so as to form an angle b which is greater than or equal to 60° and less than or equal to 70° with respect to the first cells 110a and 110b, respectively. The details of the angle a and the angle b will be described later together with an effect of the module.

Here, the first cells 110a and 110b may have different sizes, and the second cells 120a and 120b may have different sizes; they each may have an appropriate size in consideration of the side surface of the cell stand 150. Needless to say, the first cells 110a and 110b may have the same size, and the second cells 120a and 120b may have the same size.

Note that cells having different areas and incident angels of sunlight have different amounts of power generation; thus, when these cells are connected in series, one of them might function as a resistor, which leads to loss in generated power. Therefore, the first cells 110a and 110b and the second cells 120a and 120b are preferably connected in parallel. For example, a structure may be employed in which cells for one column in a lengthwise direction in FIG. 1A are connected in series and columns of cells may be connected in parallel. Note that parallel connection includes, in its category, connection through a DCDC converter.

The sealing resin 160 and the protective substrate 180 are formed over the cells. Ethylene vinyl acetate (EVA) or a silicone resin may be used for the sealing resin 160, and a glass substrate such as a clear flat glass substrate or a resin substrate having weather resistance may be used for the protective substrate 180. When the sealing resin 160 is formed using a material whose refractive index is close to that of the protective substrate 180, loss in the amount of incident light due to light reflection at the interface between materials of the module can be suppressed. Note that the protective substrate 180 is disposed so as to be substantially parallel to the supporting substrate 170, whereby a surface of the solar cell module can be planar, and a reduction in conversion efficiency due to deposition of dust or the like can be prevented.

Next, an effect of the structure of the solar cell module 100 will be described.

In the structure of the solar cell module 100, the cell is fixed to the side surface of the cell stand having a triangle prism shape; thus, the light-receiving area can be increased as compared to the case where the cell is fixed to a plane surface on the supporting substrate 170. For example, in the case where the angle a and the angle b are each 60°, the effective area of the supporting substrate needed for disposing one cell is about ½ of that in the case where one cell is disposed on the plane surface on the supporting substrate 170. Therefore, the light-receiving area of the solar cell module 100 is about twice as large as the light-receiving area of a conventional solar cell module per unit area. However, the amount of light received by the cell is also about ½ of that received by a cell of a conventional solar cell module; thus, the calculated conversion efficiency of the module is hardly changed.

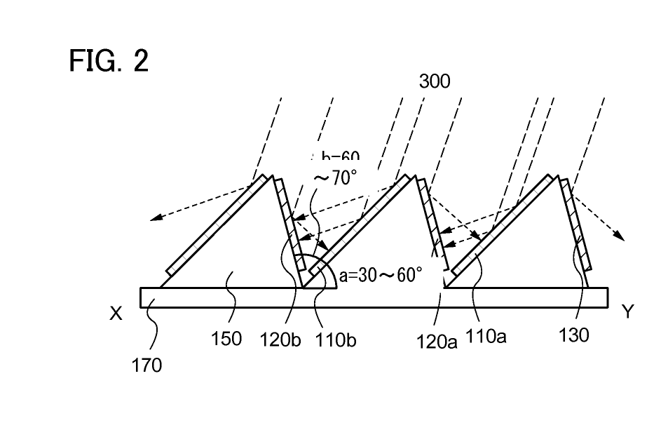

However, when the cell is irradiated with light 300 as illustrated in FIG. 2, the light 300 is partly reflected by a surface of the cell and is delivered to the opposite cell. This reflected light is effectively utilized for generating power; therefore, the conversion efficiency of the module can be improved as compared to the case where the cell is disposed on a plane surface, which has been conventionally used. Note that in FIG. 2, the sealing resin 160 and the protective substrate 180 are omitted in order to clarify the drawing.

Here, the angle b formed by the first cell and the second cell is preferably greater than or equal to 60° and less than or equal to 70°. In such a structure where the cells are provided so as to form a V shape, when the light 300 enters the cell with an appropriate angle, the reflected light is delivered to the opposite cell almost perpendicularly as illustrated in the drawing; thus, the amount of light reflected again is small, so that the light use efficiency is improved. Note that when a cell whose surface has a texture structure is used, the light use efficiency is further improved; therefore, the amount of power generation can be increased.

In the case where cells (without surface texture) with a size of 5 inches square which were formed using single crystal silicon were disposed over the supporting substrate so that the angle a and the angle b were each 60°, and the cells were irradiated with light perpendicularly to the supporting substrate, the conversion efficiency was higher by 2% than that in the case where the cells were disposed on a plane surface.

Consequently, one of characteristics of one embodiment of the present invention is that, in a structure of one pair of cells disposed so as to form a V shape, light reflected by one cell is directly utilized for photoelectric conversion of the other cell. In a conventional module where cells are disposed on a plane surface, light reflected by one cell is further reflected by a protective substrate or the like, and is delivered to another cell in some cases; however, the attenuation rate of reflected light is high, and the reflected light hardly contributes to the photoelectric conversion.

Here, in order to improve the conversion efficiency of the solar cell module 100 as described above, the installation direction of the module and the irradiation direction of the light 300 need to be appropriate.

First, the installation direction of the module is preferably set so that the X-Y direction of FIGS. 1A and 1B is a south-north direction or a north-south direction. With such an installation direction, for example, in the case where the module is irradiated with the light 300 with the angle illustrated in FIG. 2 at the time of culmination, the shade is not made on the cell even when the solar altitude is low, e.g., at around sunrise or sunset; thus, a large amount of power generation can be obtained. On the other hand, in the case where the X-Y direction is an east-west direction or a west-east direction, there is no problem during a period in which the solar altitude is high; however, during a period in which the solar altitude is low, the shade made due to the cell stand 150 having a triangle prism shape is made on the cell, so that the amount of power generation is extremely decreased.

The irradiation direction of light delivered to the module is controlled by adjusting the angle a of the cell stand 150. By adjusting the angle a, the angle of light delivered to the cell can be controlled; thus, the module can be installed without being inclined.

Since an appropriate value of the angle a differs depending on the latitude of an area where the module is set, the season, and the like, the angle a may be determined in consideration of the culmination altitude in each case. Note that in the case where the angle a is less than 30°, the size of the first cell and that of the second cell are largely different from each other; thus, an effect of reflected light described above cannot be sufficiently obtained. Therefore, the angle a is preferably greater than or equal to 30° and less than or equal to 60°. Note that the angle a may be compensated for by inclining the module slightly (the inclination angle is less than 10°).

In such a manner, the solar cell module 100 is set over a mounting rack in the state where it is hardly inclined, e.g., in the state where it is inclined with an inclination angle greater than or equal to 0° and less than 10°, whereby the amount of power generation can be increased.

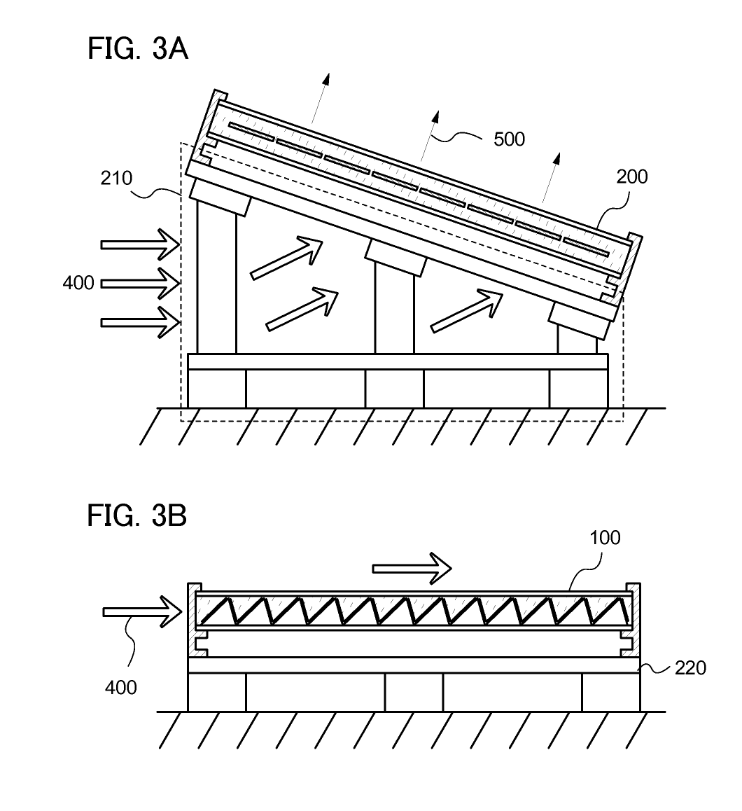

As illustrated in FIG. 3A, a conventional solar cell module 200 is installed on a mounting rack 210 so as to be inclined for increasing the amount of power generation; therefore, the area exposed to the wind is large, and the possibility that the solar cell module 200 is damaged by the wind becomes high. Note that a mounting rack does not include a substruction, a foundation, or the like in some cases; however, a support for installing the solar cell module is expressed as a mounting rack here.

When wind 400 blows toward the back side of the solar cell module 200, force 500 for lifting the module is generated; thus, the module is blown away and the mounting rack is destroyed in some cases. Therefore, in order to prevent the solar cell module 200 from being damaged by the wind, a strong mounting rack is needed for installing the conventional solar cell module 200.

On the other hand, the solar cell module 100 which is one embodiment of the present invention can be installed substantially horizontally to the level ground without decreasing the amount of power generation; thus, the area exposed to the wind is small as illustrated in FIG. 3B, and force for lifting the module is not easily generated. Therefore, the solar cell module 100 can be installed without at least a strong and expensive mounting rack for installing the module with an inclination angle, and an inexpensive mounting rack 220 for installing the module substantially parallel to the ground may be used.

As described above, with the use of the solar cell module 100, a solar photovoltaic system that withstands wind pressure as required by laws or regulations in a country where the solar cell module is installed and that can be installed at low cost can be realized.

### EXPLANATION OF REFERENCE

100: solar cell module, 110a: first cell, 110b: first cell, 120a: second cell, 120b: second cell, 130: third cell, 140: fourth cell, 150: stand, 160: sealing resin, 170: supporting substrate, 180: protective substrate, 200: solar cell module, 210: mounting rack, 220: mounting rack, 300: light, 400: wind, and 500: force

This application is based on Japanese Patent Application serial no. 2010-217099 filed with Japan Patent Office on Sep. 28, 2010, the entire contents of which are hereby incorporated by reference.

1. A solar cell module comprising:
a supporting substrate;
a first cell;
a second cell; and
a protective substrate over the supporting substrate,
wherein the first cell is disposed so as to form an angle a between a bottom surface of the first cell and a top surface of the supporting substrate,
wherein the second cell is disposed so as to form the angle a+an angle b between a bottom surface of the second cell and the top surface of the supporting substrate, the angle b being between the bottom surface of the second cell and the bottom surface of the first cell, and
wherein the first cell and the second cell are disposed so that a light-receiving surface of the first cell and a light-receiving surface of the second cell face each other.

2. The solar cell module according to claim 1, wherein the angle a is greater than or equal to 30° and less than or equal to 60°.

3. The solar cell module according to claim 1, wherein the angle b is greater than or equal to 60° and less than or equal to 70°.

4. The solar cell module according to claim 1, wherein the first cell and the second cell are electrically connected in parallel.

5. The solar cell module according to claim 1, wherein the supporting substrate and the protective substrate are substantially parallel to each other.

6. The solar cell module according to claim 1, further comprising a sealing resin between the protective substrate and the first cell and between the protective substrate and the second cell.

7. A solar cell module comprising:
a supporting substrate;
a first cell stand having a first surface and a second surface;
a first cell;
a second cell stand having a first surface and a second surface;
a second cell; and
a protective substrate over the supporting substrate,
wherein the first surface of the first cell stand and the first surface of the second cell stand are in contact with the supporting substrate,
wherein the first cell is disposed on the second surface of the first cell stand so as to form an angle a between a bottom surface of the first cell and a top surface of the supporting substrate,
wherein the second cell is disposed on the second surface of the second cell stand so as to form the angle a+an angle b between a bottom surface of the second cell and the top surface of the supporting substrate, the angle b being between the bottom surface of the second cell and the bottom surface of the first cell, and
wherein the first cell and the second cell are disposed so that a light-receiving surface of the first cell and a light-receiving surface of the second cell face each other.

8. The solar cell module according to claim 7, wherein the angle a is greater than or equal to 30° and less than or equal to 60°.

9. The solar cell module according to claim 7, wherein the angle b is greater than or equal to 60° and less than or equal to 70°.

10. The solar cell module according to claim 7, wherein the first cell and the second cell are electrically connected in parallel.

11. The solar cell module according to claim 7, wherein the supporting substrate and the protective substrate are substantially parallel to each other.

12. The solar cell module according to claim 7, further comprising a sealing resin between the protective substrate and the first cell and between the protective substrate and the second cell.

13. The solar cell module according to claim 7, wherein the first cell stand has a triangle prism shape and the second cell stand has a triangle prism shape.

14. A solar photovoltaic system comprising:
a mounting rack; and
a solar cell module attached to the mounting rack, the solar cell module comprising:
a supporting substrate;
a first cell;
a second cell; and
a protective substrate over the supporting substrate,
wherein the first cell is disposed so as to form an angle a between a bottom surface of the first cell and a top surface of the supporting substrate,
wherein the second cell is disposed so as to form the angle a+an angle b between a bottom surface of the second cell and the top surface of the supporting substrate, the angle b being between the bottom surface of the second cell and the bottom surface of the first cell,
wherein the first cell and the second cell are disposed so that a light-receiving surface of the first cell and a light-receiving surface of the second cell face each other, and
wherein the solar cell module is installed with an inclination angle greater than or equal to 0° and less than 10° to an installation surface.

15. The solar cell module according to claim 14, wherein the angle a is greater than or equal to 30° and less than or equal to 60°.

16. The solar cell module according to claim 14, wherein the angle b is greater than or equal to 60° and less than or equal to 70°.

17. The solar cell module according to claim 14, wherein the first cell and the second cell are electrically connected in parallel.

18. The solar cell module according to claim 14, wherein the supporting substrate and the protective substrate are substantially parallel to each other.

19. The solar cell module according to claim 14, further comprising a sealing resin between the protective substrate and the first cell and between the protective substrate and the second cell.

20. A solar photovoltaic system comprising:
a mounting rack; and
a solar cell module attached to the mounting rack, the solar cell module comprising:
a supporting substrate;
a first cell stand having a first surface and a second surface;
a first cell;
a second cell stand having a first surface and a second surface;
a second cell; and
a protective substrate over the supporting substrate,
wherein the first surface of the first cell stand and the first surface of the second cell stand are in contact with the supporting substrate,
wherein the first cell is disposed on the second surface of the first cell stand so as to form an angle a between a bottom surface of the first cell and a top surface of the supporting substrate,
wherein the second cell is disposed on the second surface of the second cell stand so as to form the angle a+an angle b between a bottom surface of the second cell and the top surface of the supporting substrate, the angle b being between the bottom surface of the second cell and the bottom surface of the first cell,
wherein the first cell and the second cell are disposed so that a light-receiving surface of the first cell and a light-receiving surface of the second cell face each other, and
wherein the solar cell module is installed with an inclination angle greater than or equal to 0° and less than 10° to an installation surface.

21. The solar cell module according to claim 20, wherein the angle a is greater than or equal to 30° and less than or equal to 60°.

22. The solar cell module according to claim 20, wherein the angle b is greater than or equal to 60° and less than or equal to 70°.

23. The solar cell module according to claim 20, wherein the first cell and the second cell are electrically connected in parallel.

24. The solar cell module according to claim 20, wherein the supporting substrate and the protective substrate are substantially parallel to each other.

25. The solar cell module according to claim 20, further comprising a sealing resin between the protective substrate and the first cell and between the protective substrate and the second cell.

26. The solar cell module according to claim 20, wherein the first cell stand has a triangle prism shape and the second cell stand has a triangle prism shape.
